(19) United States
(12) Patent Application Publication
(10) Pub. No.: US 2013/0063174 A1
(43) Pub. Date: Mar. 14, 2013

(54) SOLAR SIMULATOR AND SOLAR CELL INSPECTION DEVICE

(71) Applicants: Masanori Ooto, Higashiyamato-city (JP); Ryouichi Higashi, Higashiyamato-city (JP); Tetsuya Saito, Higashiyamato-city (JP)

(72) Inventors: Masanori Ooto, Higashiyamato-city (JP); Ryouichi Higashi, Higashiyamato-city (JP); Tetsuya Saito, Higashiyamato-city (JP)

(73) Assignee: FUJI ELECTRIC CO., LTD., Kawasaki-Shi (JP)

(21) Appl. No.: 13/390,102

(22) PCT Filed: Feb. 14, 2011
(86) PCT No.: PCT/JP2011/052989

§ 371 Date: Apr. 20, 2012

(30) Foreign Application Priority Data
Jun. 4, 2010 (JP) 2010-129208

(51) Int. Cl. G01R 31/26; F21V 7/00

(52) U.S. Cl. 324/761.01; 362/1

(57) ABSTRACT

A solar simulator in which locational unevenness of irradiance is reduced by using a small and simple optical system, having an array of light emitters 2 with a plurality of point light emitters planarly arranged in a given range 24, an effective irradiated region 4 spaced apart from a surface having the point light emitters 26 arranged thereon, and a reflection mirror 6 disposed to surround the given range 24 of the array. Preferably, a distance L between the point light emitter positioned at the outermost portion of given range 24 of the array of light emitters 2 and a light-reflecting surface of the reflection mirror is half of a pitch a of the array of the point light emitters and, more preferably, the distance L is larger than half of a width b of each point light emitter, and smaller than half of the pitch a.

### CROSS-REFERENCE TO RELATED APPLICATIONS

The present application is the national phase of PCT patent application PCT/JP2011/052989, filed on Feb. 14, 2011, which claims priority from Japanese patent application 2010-129208, filed on Jun. 4, 2010.

### FIELD OF THE INVENTION

The present invention relates to a solar simulator and a solar cell inspection device each for inspecting a solar cell. More specifically, the invention relates to a solar simulator using an array of light emitters including point light emitters, and a solar cell inspection device using the solar simulator.

### BACKGROUND ART

Conventionally, in order to inspect photoelectric conversion characteristics of a produced solar cell, electrical output characteristics of the solar cell are measured while the solar cell is irradiated with predetermined light. In the measurement, there is used a light emitter device for irradiating the solar cell with light satisfying predetermined conditions, i.e., a solar simulator.

In the solar simulator, in order to generate irradiation light having a spectrum similar to that of sunlight, in many cases, a combination of a light emitting body such as, e.g., a xenon lamp or a halogen lamp with an appropriate filter is used as a light emitter. Particularly, in the solar simulator for inspecting mass-produced solar cells, in addition to the above spectrum, a light intensity on a light-receiving surface of the solar cell, i.e., irradiance is carefully equalized. This is because quality control of the mass-produced solar cell is conducted on the basis of measured photoelectric conversion characteristics, and hence the measurement result is compared or contrasted to those of other solar cells. Hereinafter, in the solar simulator, a surface irradiated with light for measuring the solar cell is referred to as an “irradiated surface” and, in the irradiated surface, the range where the light-receiving surface of the solar cell is assumed to be positioned is referred to as an “effective irradiated region”. In addition, inequality of irradiance in individual positions (locations) in the effective irradiated region, i.e., non-uniformity thereof is referred to as “locational unevenness of irradiance”. Note that, in JIS C 8912 and JIS C 8933, “4.2 measurement of locational unevenness of irradiance” is defined. In addition, in IEC 60904-9: 2007 “Photovoltatic devices: Part 9 Solar simulator performance requirements”, “3.10 non uniformity of irradiance in the test plane” is defined as a term.

In the conventional solar simulator, in order to equalize the irradiance in the effective irradiated region, a diffusing optical system or an integrating optical system is disposed at any position between the light emitter and the irradiated surface. Each of these optical systems is an optical element for equalizing the irradiance in the effective irradiated region by diffusing or condensing light from the light emitter to control the direction of the light at some midpoint of the distance of propagation of the light. For example, when trying to equalize the irradiance according to the conventional method for the measurement of a large-area solar cell such as an integrated solar cell, it becomes necessary to increase the distance of propagation of the light in accordance with the size of the measurement target solar cell (solar cell to be measured). As a result, the solar simulator using the conventional method in which the large-area solar cell is irradiated at the equalized irradiance inevitably occupies a large space.

On the other hand, as the light emitter of the solar simulator, there is proposed the use of a plate-like light emitter unit in which solid-state light emitters such as a light emitting diode (LED) and the like are planarly arranged (for example, the Japanese Translation of PCT Application No. 2004-511918, and Japanese Laid-open Patent Application No. 2004-281706). As in the proposals, when the plate-like light emitter unit is applied to the solar simulator, by arranging several plate-like light emitter units into the shape of arranged tiles, it becomes possible to easily enlarge the effective irradiated region. In the solar simulator using such plate-late light emitter unit, it is possible to reduce an optical path length from the light emitter to the irradiated surface to be shorter than that in the solar simulator using the xenon lamp or the halogen lamp. This is because, between the light emitter and the irradiated surface, a large-scale optical system for equalizing the irradiance is not required. Thus, when the plate-like light emitter unit is used, it becomes easy to cope with an increase in the size of the solar cell, and an advantage is also achieved that an increase in the size of the solar simulator itself is easily suppressed.

Herein, one of characteristics of the solar simulator required when solar cells of various sizes are inspected is that the irradiance is as constant, i.e., uniform as possible throughout the effective irradiated region. However, in each of the solar simulators disclosed in PCT Application No. 2004-511918, and Japanese Laid-open Patent Application No. 2004-281706, which use the plate-like light emitter unit in which a plurality of solid-state light emitters are arranged, the problem is encountered that the irradiance tends to be lowered in the vicinity of the peripheral edge portion of the effective irradiated region so that the locational unevenness of irradiance tends to be increased. The present invention is intended to contribute to the provision of a solar simulator in which the lowering of the irradiance in the vicinity of the peripheral edge portion of the effective irradiated region is prevented, and the locational unevenness of irradiance is reduced.

In order to solve the problem described above, the inventors of the present application reexamined the configuration of the solar simulator using the plate-like array of light emitters in which a large number of light emitters having minute light emitting bodies (hereinafter referred to as “point light emitters”) are used. In such solar simulator, light incident on each position in the effective irradiated region is light emitted from a plurality of point light emitters. Therefore, the number of point light emitters contributing to the irradiation of the light at each location of the effective irradiated region is preferably as constant as possible. However, in the solar simulator using the plate-like array of light emitters, the number of point light emitters contributing to the irradiation is large in the central portion of the effective irradiated region, while in the vicinity of the peripheral edge portion of the effective irradiated region, the number thereof is smaller than the number thereof in the central portion. The inventors considered that the cause for the increase in the locational unevenness of irradiance resulting from the lowering of the irradiance in the vicinity of the peripheral edge portion of the effective irradiated region lay in the difference in the number of point light emitters contributing to the light irradiation depending on the location in the effective irradiated region, more specifically, the substantial reduction in the number of point light emitters in the vicinity of the peripheral edge portion of the effective irradiated region.

Consequently, the invertors of the present invention reached a conclusion that, in order to reduce the locational unevenness of irradiance as much as possible by using the point light emitter, it was effective to equalize the substantial number of light emitters for irradiation in the vicinity of the peripheral edge portion of the effective irradiated region to that of the central portion thereof. Specifically, it is effective to dispose a reflection mirror around the effective irradiated region. The function which the reflection mirror is caused to carry out is a function of redirecting light travelling from the point light emitter disposed at a position opposing the effective irradiated region toward the outside of the effective irradiated region to the inside of the effective irradiated region by reflection.

### SUMMARY OF THE INVENTION

That is, in an aspect of the present invention, there is provided a solar simulator including an array of light emitters having a plurality of point light emitters planarly arranged in a given range, an effective irradiated region which is disposed to be spaced apart from a surface having the point light emitters arranged thereon in the array of light emitters, receives light from the array of light emitters, and has a light-receiving surface of a target solar cell to be inspected disposed on at least a part thereof, and a reflection mirror which is disposed so as to surround the given range in the array of light emitters.

Further, in another aspect of the present invention, there is provided a solar simulator including an array of light emitters having a plurality of point light emitters planarly arranged in a given range, an effective irradiated region which is disposed to be spaced apart from a surface having the point light emitters arranged thereon in the array of light emitters, receives light from the array of light emitters, and has a light-receiving surface of an target solar cell to be inspected disposed on at least a part thereof, and a reflection mirror which is disposed so as to surround the effective irradiated region.

In addition, in still another aspect of the present invention, there is provided a solar simulator including an array of light emitters having a plurality of point light emitters planarly arranged in a given range, an effective irradiated region which is disposed to be spaced apart from a surface having the point light emitters arranged thereon in the array of light emitters, receives light from the array of light emitters, and has a light-receiving surface of a target solar cell to be inspected disposed on at least a part thereof, and a reflection mirror which is disposed so as to surround a planar region across which the light travelling from the array of light emitters toward the effective irradiated region passes.

In each of the above aspects of the present invention, the reflection mirror disposed “so as to surround” the given range in the array of light emitters typically includes a disposition carrying out an optical function in which, by reflecting light incident on the reflection mirror from the point light emitters included in the array of light emitters, the reflection mirror reflects the light toward the space on the side of the given range of the array of light emitters. Consequently, the thus defined reflection mirror denotes a reflection mirror which is disposed in a substantial portion at a position corresponding to the outer periphery of the given range of the array of light emitters. The definition of the reflection mirror does not require the reflection mirror to completely surround the outer periphery of the given range of the array of light emitters without any gap. This point also applies to the case where the reflection mirror surrounds the effective irradiated region, or the case where the reflection mirror surrounds the planar region. Note that the “array of light sources” denotes a light emitter set including several light emitters which are arranged in any manner. In addition, the “point light emitter” denotes a light emitter which emits light in a minute region, and is not limited to a light emitter in which light is emitted only from a point in the sense of geometry.

According to any aspect of the present invention, in the solar simulator for measuring photoelectric conversion characteristics of the solar cell, irradiation of light having high equality with reduced locational unevenness of irradiance is achieved.

### BRIEF DESCRIPTION OF THE DRAWINGS

FIG. 1 is a perspective view showing a schematic configuration of a solar cell inspection device of an embodiment of the present invention;

FIG. 2 includes a schematic cross-sectional view (FIG. 2(a)) and a schematic plan view (FIG. 2(b)) showing a schematic configuration of a solar simulator in the solar cell inspection device of the embodiment of the present invention;

FIG. 3 is a plan view showing a typical array of point light emitters in a light emitter unit in the solar simulator in the embodiment of the present invention;

FIG. 4 is a plan view showing a typical array of point light emitters in a light emitter unit in the solar simulator in the embodiment of the present invention;

FIG. 5 is a cross-sectional view showing the enlarged array of light emitters in the embodiment of the present invention;

FIG. 6 is a graph showing measurement results of a large-size solar cell and a small-size solar cell measured by a solar cell inspection device employing a conventional solar simulator, and includes a current/voltage characteristic view (FIG. 6(a)) and electric power characteristics (FIG. 6(b)); and

FIG. 7 is a graph showing measurement results of the large-size solar cell and the small-size solar cell measured by the solar cell inspection device employing the solar simulator in the embodiment of the present invention, and includes a current/voltage characteristic view (FIG. 7(a)) and electric power characteristics (FIG. 7(b)).

### DETAILED DESCRIPTION OF THE INVENTION

A description is given hereinbelow of embodiments of the present invention. In the following description, sections or elements common in all of the drawings are designated by common reference numerals unless otherwise specified. In addition, in the drawings, the individual elements of each embodiment are not necessarily shown with mutual scales maintained.

### First Embodiment

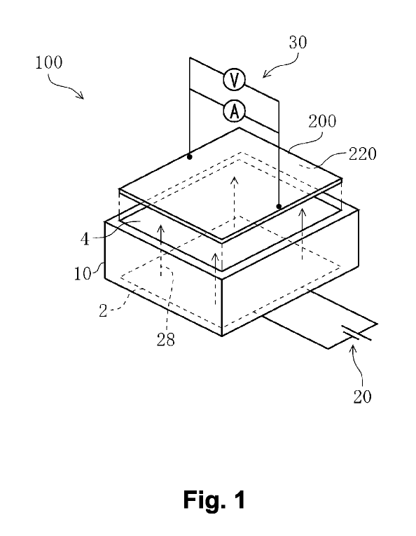

FIG. 1 is a perspective view showing a schematic configuration of a solar cell inspection device 100 of the present embodiment. The solar cell inspection device 100 of the present embodiment includes a solar simulator 10, a light quantity control section 20, and an electrical measurement section 30. The light quantity control section 20 is connected to the solar simulator 10, and controls the intensity of light 28 emitted by an array of light emitters 2 in the solar simulator 10. In addition, the electrical measurement section 30 is electrically connected to a solar cell to be measured 200 (hereinafter referred to as a “solar cell 200”), and measures current/voltage characteristics (I-V characteristics) while applying an electric load to the solar cell 200. The solar cell inspection device 100 emits the light 28 having a predetermined irradiance set by the solar simulator 10 to a light-receiving surface 220 of the solar cell 200 positioned on an effective irradiated region 4. From the current/voltage characteristics of the solar cell 200 measured by the electrical measurement section 30 in a state where the light is emitted, as numerical indicators for photoelectric conversion characteristics of the solar cell 200, numerical indicators such as, e.g., an open-circuit voltage value, a short-circuit current value, conversion efficiency, and a fill factor can be determined. Note that the solar cell 200 is disposed such that the light-receiving surface 220 of the solar cell 200 is positioned on at least a part of the effective irradiated region 4 of the solar simulator 10.

### [Configuration of Solar Simulator]

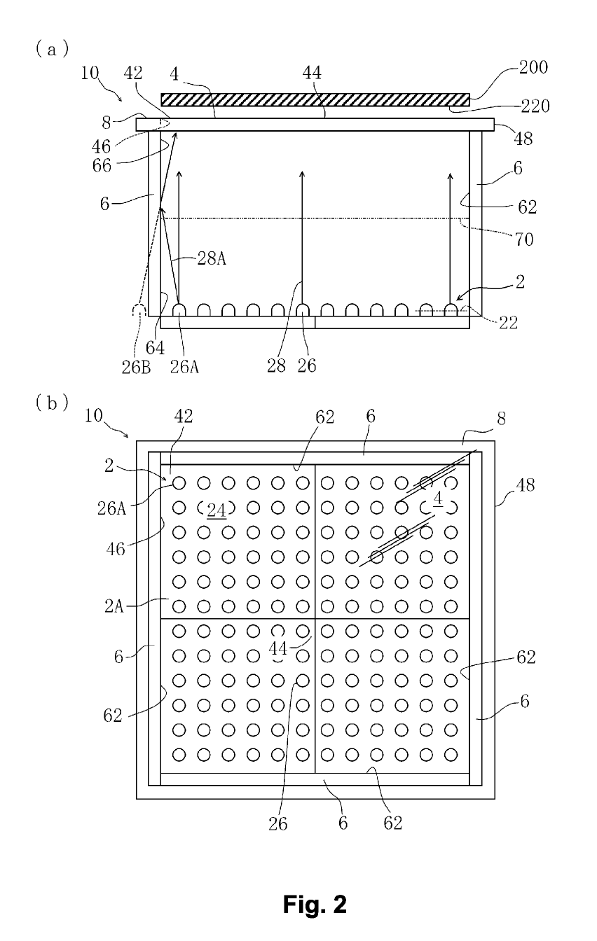

The configuration of the solar simulator 10 is further described. FIG. 2 includes a schematic cross-sectional view (FIG. 2(a)) and a schematic plan view (FIG. 2(b)) showing the schematic configuration of the solar simulator 10 of the solar cell inspection device 100 of the present embodiment. The schematic cross-sectional view (FIG. 2(a)) schematically shows the disposition of the solar cell 200. The solar simulator 10 includes the array of light emitters 2, the effective irradiated region 4, and reflection mirrors 6.

The effective irradiated region 4 is a part of an irradiated surface 8 disposed to be spaced apart from a light-emitting surface 22 of the array of light emitters 2, and denotes the range of the irradiated surface 8 on which the light-receiving surface 220 of the solar cell 200 is assumed to be positioned. Consequently, the effective irradiated region 4 serves as a region which receives the light 28 from the array of light emitters 2, and has the light-receiving surface 220 of the target solar cell 200 to be inspected disposed on at least a part thereof.

### [Reflection Mirror]

The reflection mirrors 6 are disposed so as to surround a given range 24 of the array of light emitters 2. The specific disposition of the reflection mirrors 6 is typically as follows. First of all, the array of light emitters 2 has a plurality of point light emitters 26 which are arranged so as to be planarly scattered over the given range 24. The given range 24 is a spread surface including the point light emitters 26, i.e., a planar region of the light-emitting surface 22 in the given range where the point light emitters 26 are arranged. Herein, there is assumed a pillar-like solid body having one of the given range 24 of the array of light emitters 2 and the effective irradiated region 4 which are disposed as described above as its upper surface and having the other one thereof as the bottom surface. The reflection mirrors 6 are disposed at positions on the side surfaces of the pillar-like solid body. For example, as shown in FIG. 2, when both of the given range 24 of the array of light emitters 2 and the effective irradiated region 4 are in the same rectangular shape, the given range 24 of the array of light emitters 2, the effective irradiated region 4, and the reflection mirrors 6 form a quadrangular prism, and the mirrors 6 are disposed at positions on the side surfaces of the quadrangular prism. Note that, in the typical example shown in FIG. 2, the given range 24 of the array of light emitters 2 is formed in the same shape as that of the corresponding effective irradiated region 4. In addition, the effective irradiated region 4 and the light-emitting surface 22 of the array of light emitters 2 make a pair of surfaces which are spaced apart from each other in parallel with each other, and the reflection mirrors 6 are vertically oriented relative to the effective irradiated region 4 and the light-emitting surface 22 of the array of light emitters.

The expected function of each of the reflection mirrors 6 is a function of preventing the lowering of the irradiance in a vicinity of a peripheral edge portion 42 of the effective irradiated region 4. That is, as for light 28A emitted from a point light emitter 26A of the array of light emitters 2 corresponding to the vicinity of the peripheral edge portion 42 of the effective irradiated region 4, a light beam travelling toward the outside of an outer edge 46 of the effective irradiated region 4 as a part of the light 28A enters into the reflection mirror 6. The light 28A after being reflected travels while maintaining its component perpendicular to both of the effective irradiated region 4 and the light-emitting surface 22 of the array of light emitters 2 (a component in the vertical direction in the paper sheet of FIG. 2(a)) and inverting its component in a direction of the normal to the reflection mirror 6 (a component in the left-to-right direction in FIG. 2(a)) so that the light 28A becomes irradiation light which looks as if the irradiation light is emitted from the outside of the reflection mirror 6 to the peripheral edge portion 42 of the effective irradiated region 4. By the effect of the reflection, the lowering of the irradiance is reduced even in the peripheral edge portion 42 of the effective irradiated region 4. In order to obtain such function, the reflection mirror 6 is disposed as in the typical example described above. The reflection function of the reflection mirror 6 is typically provided to surfaces 62 on the side of the effective irradiated region 4, i.e., the surfaces 62 of the reflection mirrors 6 oriented inward in FIG. 2(b).

As the reflection mirror 6, a mirror having a sufficient reflectance in a wavelength range in the emission spectrum (radiation spectrum) of the light emitter, i.e., an emission wavelength range is selected. For example, there are used a metal reflection mirror in which a metal is formed into a layer on a substrate made of glass or the like, and a dielectric multilayer film reflection mirror in which a dielectric thin film is formed on the substrate as a multilayer film. The reflectance of the reflection mirror 6 is preferably as high as possible. For example, in the emission wavelength range, the reflectance is preferably not less than 90%.

Further, by the function of the reflection mirror 6, when the light emitter side is viewed from the position of the vicinity of the peripheral edge portion 42 of the effective irradiated region 4, the array of light emitters 2 is reflected by the reflection mirror 6, and a light emitter image 26B (FIG. 2(a)) is thereby formed. As a result, when the positions of the reflection mirrors 6 are properly determined and the individual light emitters 26 of the array of light emitters 2 are observed from the effective irradiated region 4, the array of light emitters 2 looks as if the array of light emitters 2 is spread outside the reflection mirrors 6. Consequently, even in the vicinity of the peripheral edge portion 42 of the effective irradiated region 4, light from a large number of the point light emitters 26 enters similarly to a central portion 44 of the effective irradiated region 4.

Furthermore, in the solar simulator 10, the reflection mirrors 6 are disposed so as to surround the given range 24 of the array of light emitters 2, and hence it is possible to redirect light travelling in various directions from the array of light emitters 2 to the given range 24 of the array of light emitters 2 using the reflection mirrors 6.

The solar cell 200 is disposed such that the light-receiving surface 220 is directed to the array of light emitters 2 of the solar simulator 10. Specifically, the solar cell 200 in the disposition of the solar simulator 10 of FIG. 2 is placed on, e.g., the upper surface of a glass top plate 48, and directs the light-receiving surface 220 downward in the paper sheet of FIG. 2(a). In this disposition, the light 28 for illumination is emitted toward the light-receiving surface 220 from below in FIG. 2(a).

For the top plate 48 of the solar simulator 10 shown in FIG. 2(a), a member allowing light to transmit therethrough such as a glass plate material is used. In this case, of both surfaces of the top plate 48 disposed in spaced apart relation so as to correspond to the light-emitting surface 22 of the array of light emitters 2, the effective irradiated region 4 is a part of the irradiated surface 8 serving as the upper surface in the orientation of FIG. 2(a). Accordingly, for example, the effective irradiated region 4 in the case where the top plate 48 is made of glass receives the light from the array of light emitters 2 in the lower portion of FIG. 2(a) through the top plate 48. That is, the effective irradiated region 4 is defined as a part of the irradiated surface 8 directing its front surface upward in the paper sheet of FIG. 2(a), and receives the light from below. Note that, in FIG. 2(a), the solar simulator 10 is drawn in its orientation in which the light 28 is emitted from below in the drawing. However, the disposition of the solar simulator 10 and the direction of emission of the light 28 are not particularly limited. For example, the solar simulator 10 may be disposed such that the orientation of the solar simulator 10 is any orientation and the direction of emission of the light 28 is any direction, i.e., the direction of emission of the light 28 is sideward or downward. In these cases, the top plate 48 described above is not required so that the effective irradiated region is defined by other modes. For example, when the direction of emission of the light 28 is sideward, the surface of the solar cell includes a vertical direction so that the effective irradiated region is defined by the range of an opening as an example. In addition, when the direction of emission of the light is downward, the solar cell is supported from below by a support plate with the light-receiving surface faced upward and the surface opposite to the light-receiving surface faced downward. The effective irradiated region in this case is defined by, e.g., the range of the surface of the support plate supporting the solar cell.

### [Array of Light Emitters]

The array of light emitters 2 includes the plurality of the point light emitters 26 planarly arranged in the given range 24 of the light-emitting surface 22. The given range 24 of the array of light emitters 2 is, e.g., rectangular, and in the rectangular range 24, the point light emitters 26 are disposed in the array where they are vertically and horizontally arranged at a predetermined pitch. The pitch corresponds to a distance between the centers of the two closest point light emitters 26 among the point light emitters 26. As shown in FIG. 2, it is possible to configure the array of light emitters 2 so as to be composed of, e.g., a set including one or more light emitter units 2A. In FIG. 2(b), the four light emitter units 2A having the same configuration are arranged to configure the array of light emitters 2. The light emitter unit 2A in this case includes a plurality of the point light emitters 26 arranged on a plate-like circuit board, and each point light emitter 26 is disposed and supported on the circuit board.

In the present embodiment, as each point light emitter 26 in the array of light emitters 2, a solid state light emitter (solid state light emitting element) such as a light emitting diode (LED) or the like can be used. The light emission mode of the point light emitter 26 employing the light emitting diode is not particularly limited. That is, it is possible to employ the light emitting diode having, e.g., a single color light emission mode with the emission spectrum concentrated in a narrow wavelength range. Other than this, by using the light emitting diode in which a phosphor and a single color light emitting chip are integrated, it is possible to also employ the solid state light emitter having the light emission mode providing the wider emission spectrum.

Preferably, all of the point light emitters 26 included in the array of light emitters 2 are light emitters having the same light emission mode. That is, for example, when the light emitter is the light emitting diode, it is preferable to employ the light emitting diodes of the same type which are produced so as to exhibit the same emission spectrum for all of the point light emitters 26. This is because, when the array of light emitters 2 is produced by, e.g., employing several types of the light emitting diodes having different emission wavelengths in a mixed manner, the irradiance distribution in the effective irradiated region 4 is dependent on the wavelength. By contrast, when the light emitting diodes of the same type which are produced so as to exhibit the same emission spectrum are used, the irradiance distribution in the effective irradiated region 4 becomes almost identical at any wavelength in the emission spectrum. This is because the wavelength dependence of each point light emitter 26 is suppressed.

Note that what is available as the point light emitter 26 of the present embodiment includes various light emitters such as a halogen lamp, a xenon lamp, and a metal halide lamp in addition to the light emitting diode. In addition, in the solar simulator 10 for the solar cell inspection device 100, by arranging a plurality of the light emitter units 2A into the shape of arranged tiles as the array of light emitters 2, it is possible to easily enlarge the area of the array of light emitters 2, i.e., the effective irradiated region 4. In the solar simulator 10 shown in FIG. 1, the four light emitter units 2A are disposed in the shape of arranged tiles.

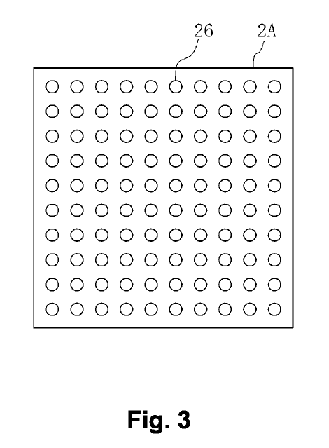

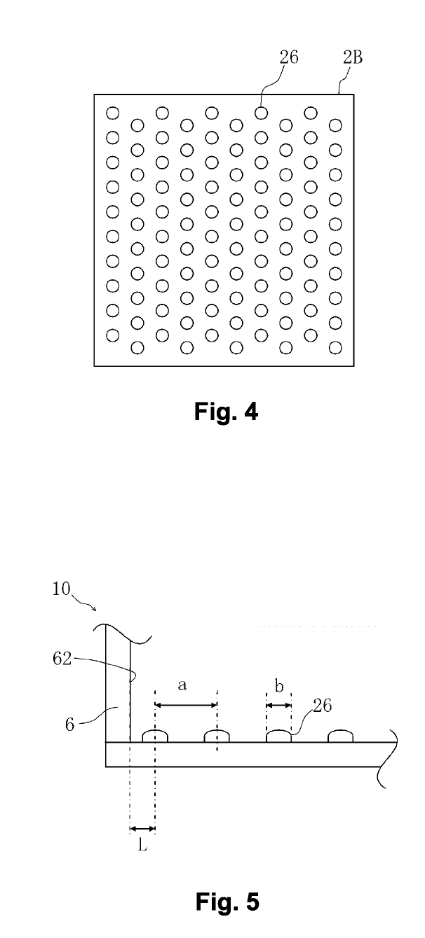

FIG. 3 is a plan view showing the typical array of the point light emitters 26 in each light emitter unit 2A in the solar simulator 10 in the present embodiment. The point light emitters 26 used in the solar simulator 10 of the present embodiment are arranged in a lattice shape, and the individual point light emitters 26 are placed at positions (lattice points) having regularity. As a result, also in the light emitter unit 2A, the point light emitters 26 have a lattice array pattern. The array pattern may have a triangular lattice in addition to a tetragonal lattice as in FIG. 3. FIG. 4 is a plan view showing the typical array of the point light emitters 26 in a light emitter unit 2B of a modification employing the triangular lattice. In the present embodiment, other than these arrays, it is also possible to use, e.g., a honeycomb-lattice array pattern (not shown).

In the present embodiment, the density of the arranged point light emitters 26, i.e., the number of point light emitters 26 per unit area is determined mainly in consideration of the required irradiance and the intensity of light emission of each point light emitter 26 (radiant flux). For example, in order to increase the irradiance of the light for irradiating the effective irradiated region 4, the density of the point light emitters 26 is increased and the total number of point light emitters 26 is also increased. When the radiant flux of each point light emitter 26 is weak as well, the density of the point light emitters 26 is increased similarly.

On the other hand, the distance from the light-emitting surface 22 of the array of light emitters 2 to the effective irradiated region 4 is determined mainly in consideration of light distribution characteristics of the point light emitter 26, i.e., radiation angle characteristics of the light. For example, when the point light emitter 26 which has the narrow light distribution characteristics and emits light by concentrating a light flux in a specific direction is used, the distance from the light-emitting surface 22 to the effective irradiated region 4 is increased. Conversely, when the point light emitter 26 which has the wide light distribution characteristics and emits light by spreading the light flux in a wide direction is used, the distance is reduced. This is because, in the case where the distance from the light-emitting surface 22 to the effective irradiated region 4 is reduced when the point light emitter 26 having the narrow light distribution characteristics is used, illuminance distributions which the individual light emitters 26 exhibit to the individual locations of the effective irradiated region 4 increase the locational unevenness of irradiance. Note that, since the reflection mirrors 6 are disposed in the present embodiment, even when the distance from the light-emitting surface 22 to the effective irradiated region 4 is increased, the irradiance of the effective irradiated region 4 is not significantly lowered.

[Relationship between Disposition of Reflection Mirror and Locational Unevenness of Irradiance]

FIG. 5 is an enlarged cross-sectional view showing the configuration of the solar simulator 10 in the present embodiment in which the lower-left portion thereof shown in FIG. 2(a) is enlarged and shown. Since the reflection mirrors 6 are used in the solar simulator 10 of the present embodiment, the irradiance in the vicinity of the peripheral edge portion 42 of the effective irradiated region 4 becomes less likely to be lowered as compared with the central portion 44 thereof. In order to enhance the equality of the irradiance in the effective irradiated region 4 to reduce the locational unevenness of irradiance, it is important to appropriately set the relative disposition of the array of light emitters 2 and the reflection mirror 6. The setting of a pitch a and a distance L shown in FIG. 5 affects the locational unevenness of irradiance. Note that the pitch a is a pitch of the array of the point light emitters in the light emitter unit, while the distance L is a distance between the central position of the point light emitter at the outermost portion closest to the mirror in the array of light emitters and the surface 62 serving as the reflecting surface of the reflection mirror 6. Hereinafter, the specific disposition of the reflection mirror 6 which determines the relationship between the pitch a and the distance L is further described on the basis of Examples of the solar simulator 10 having the configuration of the present embodiment.

### Example 1

In an Example (Example 1) of the solar simulator 10 of the present embodiment, each of the reflection mirrors 6 is disposed so as to satisfy a/2=L. Note that the reflection mirror 6 is what is called a front surface mirror, and the inside surface 62 on the side of the effective irradiated region 4 serves as the surface exhibiting reflectivity. As the reflection mirror 6, there was used a metallized surface exhibiting a reflectance of 90% to vertical incident light in the emission wavelength range.

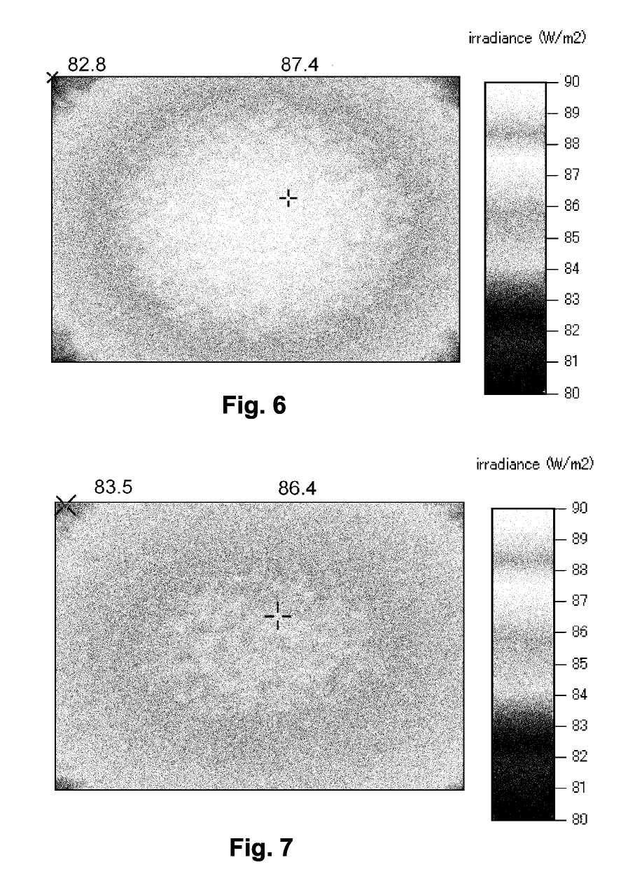

FIG. 6 is the result of calculation of values showing the irradiance distribution at each position of the effective irradiated region 4 in the configuration of the solar simulator of Example 1. The irradiance distribution is calculated by a ray-tracing method, and the value of the irradiance calculated on each position of the effective irradiated region is represented in the density at the point. Note that, at the right end of FIG. 6, an explanatory legend in which the density at the point is associated with the value of the irradiance is shown. Herein, parameters for setting the disposition of each optical element used for the calculation of the irradiance are as follows. 150 point light emitters 26 were arranged in 10 rows and 15 columns at lattice points of the tetragonal lattice, and the pitch a thereof was set to 100 mm. The reflection mirror 6 was disposed to have the distance L of 50 mm from the center of each of the circumferentially outermost point light emitters 26 among the point light emitters 26 to satisfy a/2=L. A width b of the light emitting section of each point light emitter 26 was set to 2 mm. As each point light emitter 26, there was used a light emitting diode having the radiation angle characteristics of ±60°, i.e., a light emitting diode which emits light only in a conical angular range of not more than a polar angle of 60° from the center in the direction of radiation of the light (0°). In addition, as the light emitting diode, there was used a white light emitting diode in which the phosphor is combined with a blue light emitting chip to obtain white. As the reflection mirror 6, there was used a mirror having a reflectance value of 90% on the vertical incidence in the entire range of the emission wavelength range of the irradiation light. In the calculation of the ray tracing, for the reflectance of the reflection mirror 6 in an inclination direction, the average reflectance of S-polarized light and P-polarized light was given to each inclination angle. The effective irradiated region 4 was set to a rectangular range of 1000 mm long and 1500 mm wide on the paper sheet of FIG. 6, and the distance between the given range 24 of the array of light emitters 2 and the effective irradiated region 4 was set to 500 mm.

As shown in FIG. 6, in the solar simulator of Example 1 in which the reflection mirror 6 is disposed so as to satisfy a/2=L, the values of the irradiance exhibited excellent uniformity. Specifically, the maximum irradiance and the minimum irradiance within the effective irradiated region 4 were 87.4 W/cm² and 82.8 W/cm², respectively, and the locational unevenness of irradiance calculated from these values was ±2.3%. Note that, in the method for calculating the locational unevenness of irradiance, the calculation is performed on the basis of JIS C 8933, and the number of measurement points in the calculation is 17. FIG. 6 shows positions where the maximum and minimum irradiance values were obtained, and their respective values.

The inventors of the present application considered that it was desirable to further reduce the locational unevenness of irradiance resulting from the lowering of the irradiance in the vicinity of the peripheral edge portion 42 from the irradiance values of FIG. 6 calculated in the solar simulator of Example 1 and the irradiance values in the central portion 44 and the vicinity of the peripheral edge portion 42 of the effective irradiated region 4. In particular, according to the examination of the inventors, the degree of the lowering of the irradiance becomes remarkable as the reflectance of the reflection mirror 6 is lowered. Consequently, the reflectance of the reflection mirror 6 is more preferable as the value thereof is higher and therefore, as the reflection mirror 6 in the present embodiment, there is preferably employed a mirror having, e.g., the reflectance value of not less than 90% on the vertical incidence in the entire range of the emission wavelength range of the irradiation light.

### Example 2

In an actual reflection mirror, complete reflection, i.e., the reflectance of 100% can not be achieved. This is because reflection loss can not be completely prevented. As a result, after consideration of characteristics of the actual reflection mirror, the inventors examined measures for further increasing the uniformity of the irradiance in the effective irradiated region 4. The point where attention is particularly paid is whether or not the configuration compensating for the reflection loss occurring in the actual reflection mirror 6 can be implemented. The inventors found out the configuration in which such compensation effect was exerted by adjusting the position of the reflection mirror 6 more precisely. Hereinafter, the configuration is described as Example 2.

In a solar simulator of another Example (Example 2) of the present embodiment, by moving the position of each of the reflection mirrors 6 of Example 1 described above further inward, the inevitable reflection loss in the reflection of the reflection mirror 6 is compensated for. Specifically, the reflection mirror 6 was disposed such that the distance L satisfied L=a/4, and the irradiance distribution was calculated in the disposition. Herein, those denoted by the distance L and the pitch a are the same as those in Example 1 described in connection with FIG. 5.

FIG. 7 shows the irradiance distribution at each position of the effective irradiated region 4 in the configuration of the solar simulator of Example 2. Similarly to Example 1, the irradiance distribution is calculated by the ray-tracing method. Parameters for each disposition described above were the same as those in Example 1 except that the reflection mirror 6 was disposed to have the distance L of 25 mm from the center of the circumferentially outermost point light emitter.

As shown in FIG. 7, the irradiance of the effective irradiated region 4 in the solar simulator of Example 2 exhibited more excellent uniformity than in the case of Example 1. Specifically, the maximum value and the minimum value of the irradiance in the effective irradiated region 4 were 86.4 W/cm² and 83.5 W/cm², respectively. The locational unevenness of irradiance calculated from these values was ±1.7%. Note that the number of measurement points used in the calculation thereof is the same as in Example 1.

As described thus far, in the present embodiment, by increasing the reflectance of the reflection mirror 6, it becomes possible to prevent the lowering of the irradiance in the vicinity of the peripheral edge portion 42 of the effective irradiated region 4, and by extension produce the solar simulator in which the locational unevenness of irradiance is reduced. In addition, in the present embodiment, by adjusting the position of each of the reflection mirrors 6, it becomes possible to produce the solar simulator which further reduces the locational unevenness of irradiance to emit light.

### <Modification of First Embodiment>

The above-described first embodiment can be variously modified while the advantages thereof are maintained. A representative modification thereof is described below.

First, the position of the reflection mirror can be further adjusted while the advantages of Example 2 are maintained. That is, the position of the reflection mirror is preferably adjusted in accordance with changes in conditions such as characteristics of the actually used reflection mirror or the like such that the irradiance is equalized more precisely. This is because, as long as the reflection loss of the actual reflection mirror is dependent on various conditions such as the type of the reflection mirror, the wavelength and the incident angle of light and the like, the distance L is not limited to, e.g., the one satisfying L=a/4. Typical conditions for obtaining the effect of compensating for the reflection loss of the reflection mirror by the adjustment as in Example 2 can be determined by conditions to be satisfied by the distance L. Specifically, in order to compensate for the reflection loss of the reflection mirror, the reflection mirror is preferably installed such that the distance L satisfies the relationship of b/2<L<a/2. Herein, those denoted by the distance L and the pitch a are the same as those in Example 1 described above, and the width of each point light emitter is denoted by the width b.

More specifically, the distance L is preferably less than a/2. As described above, the reflection loss is inevitable in the actual reflection mirror. This is because it is effective to position the reflection mirror further inward in order to compensate for the reflection loss. In addition, the distance L is preferably more than b/2. This is because it is necessary for the reflection mirror to be disposed outside the outermost point light emitter on the reflection mirror side in the array of light emitters. Consequently, the distance L satisfying the inequality of b/2<L<a/2 which establishes the above conditions at the same time is a range of preferable values. Note that, in Example 2 described above, the value of a is set to 100 mm and the value of b is set to 2 mm so that, even when the distance L is set to 25 mm, the relationship of b/2<L (=a/4)<a/2 is established. In addition, the purpose of requiring the distance L to satisfy b/2<L is to prevent the interference with the outermost point light emitter, and hence the width b corresponds to the width of the outermost point light emitter.

In order to determine the distance L more precisely within the range of the above conditions, various conditions are added. As the conditions, consideration is given to, e.g., the reflectance of the reflection mirror, the distance from the light emitter to the irradiated surface, the pitch of the array of the point light emitters, and the radiation angle of the point light emitter. Herein, the lowering of the equality in the vicinity of the peripheral edge portion of the effective irradiated region results from the lowering of the irradiance caused mainly by the reflection loss of the reflection mirror, i.e., the absorption. On the other hand, the effect achieved by reducing the distance L is that the irradiance in the peripheral edge portion of the effective irradiated region is increased. Therefore, the case where it is preferable to reduce the distance L is the case where the reflected light reaches further inward in the effective irradiated region, i.e., the case where the influence of the reflected light in the effective irradiated region is significant. Consequently, for example, examples of the condition under which it is preferable to further reduce the distance L includes the case where the reflectance of the reflection mirror is lower, the case where the distance from the light emitter to the irradiated surface is longer, the case where the pitch of the array of the point light emitters is narrower, and the case where the radiation angle of the point light emitter is wider.

### Another Embodiment

The above embodiment described as the first embodiment is grasped as another embodiment by defining the configuration of the reflection mirror in the solar simulator from another viewpoint. That is, in the solar simulator 10 of the first embodiment, attention is focused on the point that the reflection mirrors 6 are disposed so as to surround the effective irradiated region 4. The configuration of the reflection mirrors 6 in this manner is one of the reasons why the solar simulator 10 achieves the above-described effect in the first embodiment. This is because the portion of each of the reflection mirrors 6 close to the effective irradiated region 4, i.e., an upper portion 66 of FIG. 2(a) exerts significant influence on the irradiance in the vicinity of the peripheral edge portion 42 of the effective irradiated region 4 as compared with the portion close to the array of light emitters 2, i.e., a lower portion 64 of FIG. 2(a). Since the upper portion 66 of the reflection mirror 6 is the portion surrounding the effective irradiated region 4, the portion of the reflection mirror 6 surrounding the effective irradiated region 4 contributes to the equalization of the irradiance of the effective irradiated region 4. Thus, the disposition of the reflection mirrors so as to surround the effective irradiated region is useful for lessening the locational unevenness of irradiance. Note that, even when the reflection mirrors are disposed so as to surround the effective irradiated region, it is not essential for the reflection mirrors to completely surround the outer periphery of the effective irradiated region without any gap. Typically, as shown in FIG. 2(a), in the configuration in which the effective irradiated region 4 is positioned on the upper surface of the glass top plate 48 and each of the reflection mirrors 6 extends up to the lower surface of the top plate 48, an optical gap corresponding to the thickness of the top plate 48 is present between the effective irradiated region 4 and the upper end of the reflection mirror. Even the reflection mirrors 6 of the solar simulator 10 of the first embodiment in which such gaps are present are also considered as examples of the reflection mirrors disposed so as to surround the effective irradiated region 4.

As another general embodiment, the above-described first embodiment can also be defined as the configuration in which the reflection mirrors surround a planar region across which light travelling from the array of light emitters toward the effective irradiated region passes. A plane on which the planar region is assumed to be set is typically any plane which separates a space where the light travelling from the array of light emitters toward the effective irradiated region passes into two spaces including a space on the side of the array of light emitters and a space on the side of the effective irradiated region. The plane on which the planar region is assumed to be set is defined at any position such as the middle between the array of light emitters and the effective irradiated region or the like. The shape of the planar region is typically a shape similar or congruent to one or both of the given range of the array of light emitters and the effective irradiated region. FIG. 2(a) shows an example of position of a planar region 70 as such typical planar region by using a virtual line (two-dot chain line). The planar region 70 shown herein has a planar shape congruent to the effective irradiated region 4. Note that the reflection mirrors 6 of the solar simulator 10 in the first embodiment are disposed so as to surround the planar region 70. The portion of each of the reflection mirrors 6 surrounding the planar region 70 defined as described above also contributes to the equalization of the irradiance in the effective irradiated region 4.

Thus, any embodiment described above can obtain the effect of the first embodiment, and can be carried out according to the preferable mode similar to that in the first embodiment. That is, the use of the light emitting diode as each point light emitter in the array of light emitters, the use of the light emitters having the same light emission mode as all of the point light emitters, the use of various light emitters such as the halogen lamp, the xenon lamp, and the metal halide lamp as the point light emitter, and the arrangement of a plurality of the light emitter units into the shape of arranged tiles as the array of light emitters can be adopted in any embodiment. In addition, in any embodiment, the specific disposition of the point light emitters and the reflection mirrors shown in each of Examples 1 and 2 can be adopted.

Thus, the embodiments of the present invention have been specifically described. The above-described embodiments and Examples are described for the purpose of explaining the invention, and the scope of the invention of the present application should be defined on the basis of the description of the scope of claims. In addition, modifications within the scope of the present invention including other combinations of the individual embodiments are also included in the scope of claims.

According to the present invention, it becomes possible to provide a solar simulator having high uniformity of irradiance. Consequently, it becomes possible to perform the inspection of a solar cell with high precision in the production step of producing solar cells having various areas, which contributes to the production of the high-quality solar cell, and also contributes to the spread of any electric power equipment or electric equipment which includes such solar cell as a part thereof.

1. A solar simulator comprising:
an array of light emitters having a plurality of point light emitters arranged in a plane in a given range; and
a reflection mirror disposed to surround the given range in the array of light emitters,
wherein light from the array of light emitters is incident upon an effective irradiated region spaced laterally apart from the given region of the plane, and at least a part of the effective radiated region corresponds to a light receiving surface of a target solar cell to be inspected.

2. A solar simulator comprising:
an array of light emitters having a plurality of point light emitters arranged in a plane in a given range,
wherein light from the array of light emitters is incident upon an effective irradiated region spaced laterally apart from the given region of the plane, and at least a part of the effective radiated region corresponds to a light receiving surface of a target solar cell to be inspected; and
a reflection mirror disposed to surround the effective irradiated region.

3. A solar simulator comprising:
an array of light emitters having a plurality of point light emitters arranged in a plane in a given range,
wherein light from the array of light emitters is incident upon an effective irradiated region spaced laterally apart from the given region of the plane, and at least a part of the effective radiated region corresponds to a light receiving surface of a target solar cell to be inspected; and
a reflection mirror disposed to surround a planar region across which the light travelling from the array of light emitters toward the effective irradiated region passes.

4. The solar simulator according to claim 1, wherein the point light emitters are arranged at a constant pitch in the given range, and
a distance between a central position of the point light emitter among the point light emitters which is positioned at an outermost portion in the given range and a light-reflecting surface of the reflection mirror is set to be a half of the pitch of the point light emitters.

5. The solar simulator according to claim 1,
wherein the point light emitters are arranged at a constant pitch in the given range, and
a distance between the point light emitter among the point light emitters which is positioned at an outermost portion in the range and a light-reflecting surface of the reflection mirror is set to be larger than a half of a width of the point light emitter positioned at the outermost portion and smaller than a half of the pitch of the point light emitters.

6. The solar simulator according to claim 1, wherein each of the point light emitters is a single color light emitting diode or a light emitting diode in which a phosphor and a single color light emitting chip are integrated.

7. The solar simulator according to claim 1, wherein each of the point light emitters is a halogen lamp, a xenon lamp, or a metal halide lamp.

8. The solar simulator according to claim 1, wherein the point light emitters include only light emitters having identical light emission modes.

9. A solar cell inspection device comprising:
the solar simulator according to claim 1, further comprising:
a light quantity control section which is connected to the solar simulator to control a quantity of light emitted by the array of light emitters; and
an electrical measurement section, which is electrically connected to the target solar cell to measure a photoelectric conversion characteristic thereof while applying an electric load thereto.

10. The solar simulator according to claim 2, wherein the point light emitters are arranged at a constant pitch in the given range, and
a distance between a central position of the point light emitter among the point light emitters which is positioned at an outermost portion in the given range and a light-reflecting surface of the reflection mirror is set to be a half of the pitch of the point light emitters.

11. The solar simulator according to claim 2, wherein the point light emitters are arranged at a constant pitch in the given range, and
a distance between the point light emitter among the point light emitters which is positioned at an outermost portion in the given range and a light-reflecting surface of the reflection mirror is set to be larger than a half of a width of the point light emitter positioned at the outermost portion and smaller than a half of the pitch of the point light emitters.

12. The solar simulator according to claim 2, wherein each of the point light emitters is a single color light emitting diode or a light emitting diode in which a phosphor and a single color light emitting chip are integrated.

13. The solar simulator according to claim 2, wherein each of the point light emitters is a halogen lamp, a xenon lamp, or a metal halide lamp.

14. The solar simulator according to claim 2, wherein the point light emitters include only light emitters having identical light emission modes.

15. A solar cell inspection device comprising:
the solar simulator according to claim 2, further comprising:
a light quantity control section which is connected to the solar simulator to control a quantity of light emitted by the array of light emitters; and
an electrical measurement section, which is electrically connected to the target solar cell to measure a photoelectric conversion characteristic thereof while applying an electric load thereto.

16. The solar simulator according to claim 3, wherein the point light emitters are arranged at a constant pitch in the given range, and
a distance between a central position of the point light emitter among the point light emitters which is positioned at an outermost portion in the given range and a light-reflecting surface of the reflection mirror is set to be a half of the pitch of the point light emitters.

17. The solar simulator according to claim 3, wherein the point light emitters are arranged at a constant pitch in the given range, and
a distance between the point light emitter among the point light emitters which is positioned at an outermost portion in the given range and a light-reflecting surface of the reflection mirror is set to be larger than a half of a width of the point light emitter positioned at the outermost portion and smaller than a half of the pitch of the point light emitters.

18. The solar simulator according to claim 3, wherein each of the point light emitters is a single color light emitting diode or a light emitting diode in which a phosphor and a single color light emitting chip are integrated.

19. The solar simulator according to claim 3, wherein each of the point light emitters is a halogen lamp, a xenon lamp, or a metal halide lamp.

20. The solar simulator according to claim 3, wherein the point light emitters include only light emitters having identical light emission modes.

21. A solar cell inspection device comprising:
the solar simulator according to claim 3, further comprising:
a light quantity control section which is connected to the solar simulator to control a quantity of light emitted by the array of light emitters; and
an electrical measurement section, which is electrically connected to the target solar cell to measure a photoelectric conversion characteristic thereof while applying an electric load thereto.
